(19) United States
(12) Patent Application Publication
(10) Pub. No.: US 2026/0171349 A1
(43) Pub. Date: Jun. 18, 2026

(54) CHARGED PARTICLE BEAM DETECTOR WITH ADAPTIVE DETECTION AREA FOR MULTIPLE FIELD OF VIEW SETTINGS

(71) Applicant: ASML Netherlands B.V., Veldhoven (NL)

(72) Inventors: Zhenyang XIA, San Jose, CA (US); Yongxin WANG, San Ramon, CA (US); Xiaoyu JI, San Jose, CA (US); Jun JIANG, San Jose, CA (US); Kenichi KANAI, Palo Alto, CA (US); Yongjian ZHOU, San Jose, CA (US)

(73) Assignee: ASML Netherlands B.V., Veldhoven (NL)

(21) Appl. No.: 19/126,631

(22) PCT Filed: Oct. 30, 2023
(86) PCT No.: PCT/EP2023/080273

§ 371 Date: May 1, 2025

Related U.S. Application Data
(60) Provisional application No. 63/421,870, filed on Nov. 2, 2022.
(60) Provisional application No. 63/591,417, filed on Oct. 18, 2023.

(51) Int. Cl. H01J 37/244

(52) U.S. Cl. CPC H01J 37/244; H01J 2237/24465; H01J 2237/24495

(57) ABSTRACT

A charged particle beam detector may include a plurality of detector segments designed to accommodate a field of view (FOV) of a charged particle beam apparatus. A first detector segment may form a first detector region configured to capture emitted charged particles for a smaller FOV size. A second detector segment may surround the first detector segment to form a second detector region configured to capture emitted charged particles under larger FOV size. The first detector region may have a lower noise component due to reduced junction capacitance in the smaller detection surface area.

### CROSS-REFERENCE TO RELATED APPLICATIONS

This application claims priority of U.S. application 63/421,870 which was filed on Nov. 2, 2022 and U.S. application 63/591,417 which was filed on Oct. 18, 2023 which is incorporated herein in its entirety by reference.

### FIELD

The description herein relates to detectors that may be useful in the field of charged particle beam systems, and more particularly, to systems and methods that may be applicable to charged particle detection using charged particle counting.

### BACKGROUND

Detectors may be used for sensing physically observable phenomena. For example, charged particle beam tools, such as electron microscopes, may comprise detectors that receive charged particles projected from a sample and that output detection signals. Detection signals may be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Inspection systems may be provided for this purpose.

Existing detection systems may have an undesirably high signal-to-noise ratio (SNR). A further consideration may be a charged particle beam collection rate.

### SUMMARY

Embodiments of the present disclosure provide systems and methods for detection based on charged particle beams. Some embodiments of the present disclosure provide a segmented multi-channel detector. The segmented multi-channel detector may comprise a first detector region and a second detector region. The first detector region may have a first segment and the second detector region may have the first segment and a second segment. The second segment may surround at least 50% of the first segment. The first detector region may comprise a first noise value of a noise parameter, and the second detector region may comprise a second noise value of the noise parameter, the second noise value being higher than the first noise value.

Some embodiments of the present disclosure provide a charged particle beam apparatus comprising the segmented multi-channel detector described above. The charged particle beam apparatus may further comprise a charged particle beam source configured to generate a beam of primary charged particles, and a charged particle optical system configured to scan the beam of primary charged particles over a field of view (FOV) of the sample surface.

Some embodiments of the present disclosure provide a method of detecting a charged particle event in a charged particle detector. The method may comprise: performing a first scan of a sample surface with a charged particle beam under a first exposure setting to cause emitted charged particles from the sample surface to land in a first detector region of the charged particle detector, the first detector region comprising a first noise value of a noise parameter; generating a first image based on the first scan; performing a second scan of the sample surface with a charged particle beam under a second exposure setting to cause emitted charged particles from the sample surface to land in a second detector region of the charged particle detector, the second detector region comprising a second noise value of a noise parameter, the second noise value being higher than the first noise value; and generating a second image based on the second scan, the first image having a higher accuracy than the second image. The first detector region may comprise a first segment of the charged particle detector, and the second detector region may comprise the first segment and a second segment of the charged particle detector. The second detector region may be larger than the first detector region.

Some embodiments of the present disclosure provide a non-transitory computer-readable medium. The non-transitory computer-readable may store a set of instructions that is executable by at least one processor of an apparatus to cause the apparatus to perform the above method.

Some embodiments of the present disclosure provide a charged particle detector. The charged particle detector may comprise: a top conductive layer comprising a detection surface; a bottom conductive layer; a semiconductor region between the top conductive layer and the bottom conductive layer, the semiconductor region comprising a first doped region of a first conductivity type adjacent the top conductive layer, a second doped region of a second conductivity type adjacent the bottom conductive layer, the second conductivity type being different from the first conductivity type, and an intrinsic region between the first doped region and the second doped region; and an aperture configured to allow a primary charged particle beam to pass through, wherein the detection surface extends to an edge of the aperture.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings.

FIG. 1 is a diagrammatic representation of an exemplary electron beam inspection (EBI) system, consistent with embodiments of the present disclosure.

FIGS. 2A-C are diagrams illustrating a charged particle beam apparatus that may be an example of an electron beam tool, consistent with embodiments of the present disclosure.

FIGS. 3A-D are diagrammatic representations of a structure of a detector.

FIG. 4 is a diagrammatic representation of a sample field of view (FOV) and corresponding detection surface, consistent with embodiments of the present disclosure.

FIG. 5 is a diagrammatic representation illustrating various elements that may contribute to noise in an imaging channel of a charged particle detector, consistent with embodiments of the present disclosure.

FIGS. 6A-D are diagrammatic representations of an example segmented charged particle detector, consistent with embodiments of the present disclosure.

FIGS. 7A-C are diagrammatic representations of an example segmented charged particle detector, consistent with embodiments of the present disclosure.

FIG. 8 is a flowchart illustrating an example method for detecting charged particles, consistent with embodiments of the disclosure.

FIG. 9 is a flowchart illustrating an example method for detecting charged particles, consistent with embodiments of the disclosure.

FIGS. 10A-C are diagrammatic representations illustrating a charged particle detector, according to embodiments of the present disclosure.

FIGS. 11A-B are diagrammatic representations illustrating a charged particle detector, consistent with embodiments of the present disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims. For example, although some embodiments are described in the context of utilizing charged-particle beams (e.g., electron beams), the disclosure is not so limited. Other types of charged particle beams (e.g., photon beams) may be similarly applied. Furthermore, other imaging systems may be used, such as optical imaging, photodetection, x-ray detection, or the like.

Electronic devices are constructed of circuits formed on a piece of silicon called a substrate. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a fingernail and yet may include over 2 billion transistors, the size of each transistor being less than 1/1,000th the width of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SEM can be used to image these extremely small structures, in effect, taking a “picture” of the structures. The image can be used to determine if the structure was formed properly, and also if it was formed in the proper location. If the structure is defective, then the process can be adjusted so the defect is less likely to recur. To enhance throughput (e.g., the number of samples processed per hour), it is desirable to conduct inspection as quickly as possible.

The working principle of a SEM is similar to a raster scanning camera. A raster scanning camera takes a picture by receiving and recording intensity of light reflected or emitted from people or objects, pixel by pixel. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and, in some instances, stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

Typically, the detection process involves measuring the magnitude of an electrical signal generated when electrons land on the detector. Intensity of the secondary beam may be determined based on electrical signals generated in the detector that vary in proportion to the change in intensity of the secondary beam.

To obtain accurate intensity readings and generate an accurate image, it is important to collect as many of the emitted electrons as possible. Because electrons tend to land on a detector surface in a scattered distribution such as, e.g., a cluster that spreads out from its center, one way to achieve a higher collection rate is to provide a large detection surface area. However, some unwanted electrical effects become more pronounced with increased detection surface area. These unwanted effects can increase noise in the detection signal. For example, junction capacitance is an electrical parameter that may relate directly to a size of the detection surface. Therefore, it may be desirable to provide a detector with only as much surface area as is necessary to capture enough electrons for a given exposure.

However, electron beam tools (such as SEM tools) operate under different settings that May alter the amount of surface area needed. For example, the SEM tool might scan a large or small portion of a sample surface, the portion being known as a field of view (FOV). When a large FOV is scanned, a larger detection surface is needed to gather enough electrons for an accurate measurement. Therefore it may be desirable to provide a detector with multiple detector surface segments that are tailored to match the expected electron distribution from different FOV sizes. Conventional segmented detectors may not be designed in a manner to efficiently and effectively capture these different distributions.

Embodiments of the present disclosure may provide a segmented charged particle detector. The detector may comprise a first segment designed to capture a large portion of electrons emitted from a small FOV scan. The first segment may have a shape that matches the small FOV, such as a rectangular-based shape. For example, the rectangular-based shape may be substantially square, substantially rectangular, or it may have a shape that matches an expected electron distribution from the small FOV, such as, e.g., a distorted square shape. The first segment may form a first detection region. The first detection region may have a lower noise value due to its small size and may therefore produce a higher accuracy image.

The detector may comprise a second segment that surrounds the first segment and has a similar shape. The second segment, when combined with the first segment, may be designed to capture a large portion of electrons emitted from a large FOV scan. The first and second segments may have a shape that matches the large FOV, such as a rectangular-based shape. For example, a rectangular-based shape may be substantially square, substantially rectangular, or may be a shape that matches an expected electron distribution from the large FOV, such, e.g., a distorted square shape. The first and second segments may form a second detection region. The second detection region may have a higher noise value due to its larger size and may therefore produce a lower accuracy image. However, the second detection region may capture a larger number of electrons than the first detection region.

In this way, the detector may allow a tradeoff to be selected between noise and collection rate, depending on the parameters of a particular charged particle beam exposure. In some embodiments, a parameter other than FOV size may impact the choice of detection regions. For example, as further discussed below, the electron distribution on a detector surface may be affected by other settings in an exposure system such as landing energy.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams (such as proton beams) may be similarly applied. Furthermore, systems and methods for detection may be used in other imaging systems, such as optical imaging, photon detection, proton detection, x-ray detection, ion detection, or the like. Photon detection may comprise light in the infrared, visible, UV, DUV, EUV, x-ray, or any other wavelength range. Therefore, while detectors in the present disclosure may be disclosed with respect to electron detection, some embodiments of the present disclosure may be directed to detecting other charged particles or photons.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C.

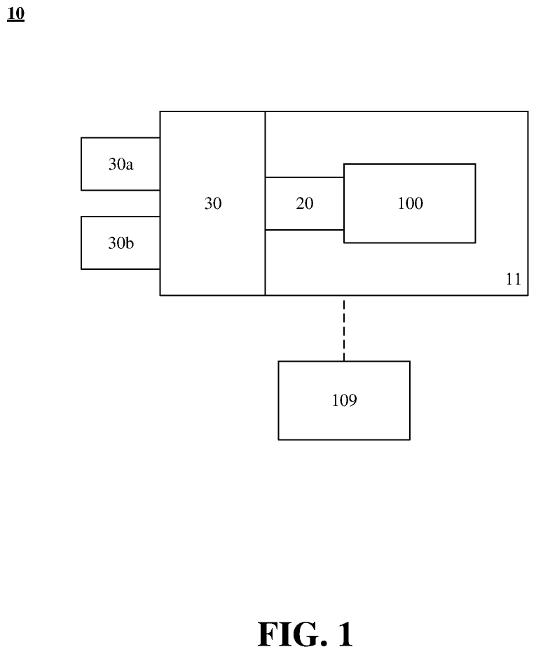

Reference is now made to FIG. 1, which illustrates an exemplary electron beam inspection (EBI) system 10 that may be used for wafer inspection, consistent with embodiments of the present disclosure. As shown in FIG. 1, EBI system 10 includes a main chamber 11 a load/lock chamber 20, an electron beam tool 100 (e.g., a scanning electron microscope (SEM)), and an equipment front end module (EFEM) 30. Electron beam tool 100 is located within main chamber 11 and may be used for imaging. EFEM 30 includes a first loading port 30a and a second loading port 30b. EFEM 30 may include additional loading ports. First loading port 30a and second loading port 30b receive wafer front opening unified pods (FOUPs) that contain wafers (e.g., semiconductor wafers or wafers made of other materials) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a wafer under inspection. The interactions of the primary electrons with the wafer may result in secondary particle beams being formed. The secondary particle beams may comprise backscattered electrons, secondary electrons, or Auger electrons, etc. resulting from the interactions of the primary electrons with the wafer. Characteristics of the secondary particle beams (e.g., intensity) may vary based on the properties of the internal or external structures or materials of the wafer, and thus may indicate whether the wafer includes defects.

The intensity of the secondary particle beams may be determined using a detector. The secondary particle beams may form beam spots on a surface of the detector. The detector may generate electrical signals (e.g., a current, a charge, a voltage, etc.) that represent intensity of the detected secondary particle beams. The electrical signals may be measured with measurement circuitries which may include further components (e.g., analog-to-digital converters) to obtain a distribution of the detected electrons. The electron distribution data collected during a detection time window, in combination with corresponding scan path data of the primary electron beam incident on the wafer surface, may be used to reconstruct images of the wafer structures or materials under inspection. The reconstructed images may be used to reveal various features of the internal or external structures or materials of the wafer and may be used to reveal defects that may exist in the wafer. There are two ways for CD-SEM to perform image reconstruction based on the signal: based on amplitude integral of the signal in each scanning pixel; or based on signal pulse edge detection and discrimination. At each scanned pixel location, multiple electrical signal pulses collected by different detector segments may have different pulse shapes. These various pulse shapes contain information about the electron energy distribution collected by the detector. Electrons with higher energy can cause faster rising times in the electrical pulse shape. With multiple segments of the detector (4 channels), up to 4 pulse edge detection image channels can be used to perform electron energy analysis, yielding higher SEM resolution.

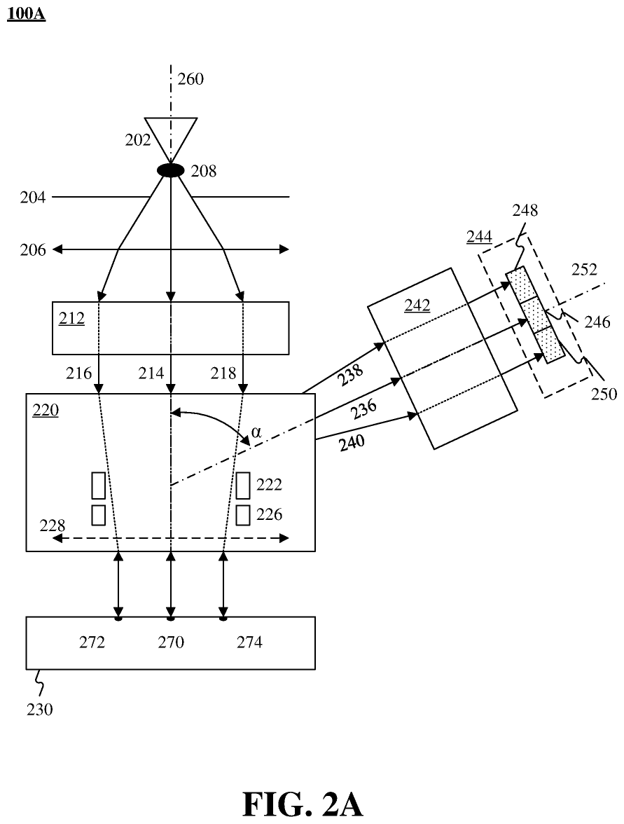

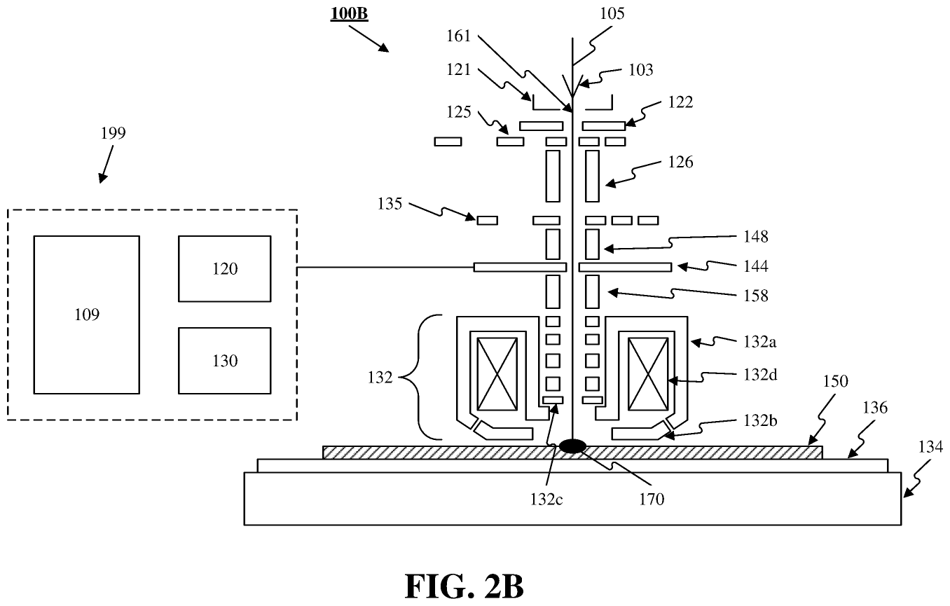

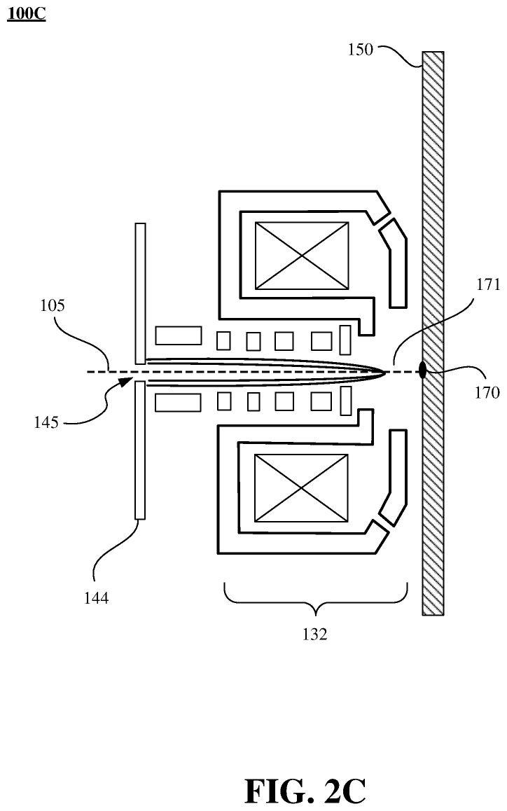

FIG. 2A illustrates a charged particle beam apparatus that may be an example of electron beam tool 100, consistent with embodiments of the present disclosure. FIG. 2A shows an apparatus that uses a plurality of beamlets formed from a primary electron beam to simultaneously scan multiple locations on a wafer.

As shown in FIG. 2A, electron beam tool 100A may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 100A. Secondary optical system 242 and electron detection device 244 may be aligned with a secondary optical axis 252 of apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principle plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230.

The generated signals may represent intensities of secondary electron beams 236, 238, and 240 and may be provided to an image processing system (e.g. such as image processing system 199 provided in FIG. 2B below) that is in communication with detection device 244, primary projection optical system 220, and motorized wafer stage. The movement speed of motorized wafer stage may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary electron beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary electron beams 236, 238, and 240 that may have different intensities. Therefore, by mapping the intensity of secondary electron beams 236, 238, and 240 with the areas of wafer 230, the image processing system may reconstruct an image that reflects the characteristics of internal or external structures of wafer 230.

Detection sub-regions 246, 248, and 250 may include separate detector packages, separate sensing elements, or separate regions of an array detector. In some embodiments, each detection sub-region may include a single sensing element.

While FIG. 2A shows detector 244 having several detection sub-regions aligned with secondary optical axis 252, it is appreciated that other multi-beam detector schemes may exist. For example, it is appreciated that a detector may correspond with each beamlet, such as a different detector for each of beamlets 214, 216, 218. It is appreciated that these different detectors may be positioned under the primary column corresponding to primary axis 260. For example, these different detectors could be positioned between primary projection optical system 220 and the wafer stage.

Another example of a charged particle beam apparatus will now be discussed with reference to FIG. 2B. An electron beam tool 100B (also referred to herein as apparatus 100B) may be an example of electron beam tool 100 and may be similar to electron beam tool 100A shown in FIG. 2A. However, different from apparatus 100A, apparatus 100B may be a single-beam tool that uses only one primary electron beam to scan one location on the wafer at a time.

As shown in FIG. 2B, apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may be communicatively coupled with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

FIG. 2B illustrates a charged particle beam apparatus that may use a single primary beam configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 2B shows an example of detector 144 having an opening at its center. However, some embodiments may use a detector placed off-axis relative to the optical axis along which the primary electron beam travels. For example, as in the embodiment shown in FIG. 2A, discussed above, a beam separator 222 may be provided to direct secondary electron beams toward a detector placed off-axis. Beam separator 222 may be configured to divert secondary electron beams by an angle α toward an electron detection device 244, as shown in FIG. 2A.

In some embodiments of the disclosure, a PIN detector may be used as an in-lens detector in a retarding objective lens SEM column of EBI system 10. The PIN detector may be placed between a cathode for generating an electron beam and the objective lens. The electron beam emitted from the cathode may be potentialized at −BE keV (typically around −10 kV). Electrons of the electron beam may be immediately accelerated and travel through the column. The column may be at ground potential. Thus, electrons may travel with kinetic energy of BE keV while passing through opening 145 of detector 144. Electrons passing through the pole piece of the objective lens, such as pole piece 132a of objective lens assembly 132 of FIG. 2B, may be steeply decelerated down to landing energy LE keV as the wafer surface potential may be set at −(BE−LE) keV.

FIG. 2C illustrates an example of a charged particle beam apparatus 100C, consistent with embodiments of the present disclosure. Charged particle beam apparatus 100C may be, e.g., charged particle beam apparatus 100A of FIG. 2A or 100B of FIG. 2B. Emitted electrons 171, comprising e.g., secondary or backscattered electrons, are emitted from the wafer surface by the impingement of electrons of the primary electron beam 105. A retarding electric field, which may slow the primary electrons as they approach probe spot 170, may act as an acceleration electric field to accelerate the emitted electrons backwards toward a detector 144 surface. For example, as shown in FIG. 2C, due to interactions with wafer 150 at probe spot 170, emitted electrons 171 may be generated that travel back toward detector 144.

Emitted electrons 171 from the wafer surface travelling along optical axis 105 may arrive at the surface of detector 144 with a distribution of positions. As discussed above, emitted electrons may comprise, e.g., secondary or backscattered electrons. In some embodiments, for example, a distribution may comprise between 60-85% secondary electrons and between 40-15% backscattered electrons. The landing point distribution may shift depending on emission position and SEM deflection fields (e.g., scan field). Therefore, in some applications, if a FOV of a SEM image is required, the required size of an in-lens PIN detector may be substantially large. Typically, a detector may be 10 mm in diameter, or larger, for example. In some embodiments, a detector may be, e.g., about 4 to 10 mm in diameter.

Detector 144 may be placed along optical axis 105. The primary electron beam may be configured to travel along optical axis 105. Accordingly, detector 144 may include a hole 145 at its center so that the primary electron beam may pass through to reach wafer 150. FIGS. 2B-C show examples of a detector 144 having an opening at its center. However, some embodiments may use a detector placed off-axis relative to the optical axis along which the primary electron beam travels. For example, as in the example shown in FIG. 2A, a beam separator 222 may be provided to direct emitted electron beams toward a detector placed off-axis. Beam separator 222 may be configured to divert emitted electron beams by an angle α toward an electron detection device 244, as shown in FIG. 2A. Therefore, in some embodiments of the present disclosure, a detector may be provided that has no central opening.

Detectors 244 of FIG. 2A or 144 of FIGS. 2B-C may include sensing elements such as diodes, or elements similar to diodes, that may convert incident energy into a measurable signal. For example, sensing elements in a detector may include a SPAD, APD, or PIN diode. Throughout this disclosure, sensing elements may be represented as a diode, although sensing elements or other components may deviate from ideal circuit behavior of electrical elements such as diodes, resistors, capacitors, etc. In embodiments of the present disclosure, a detector in a charged particle beam system may comprise a pixelated array of multiple sensing elements.

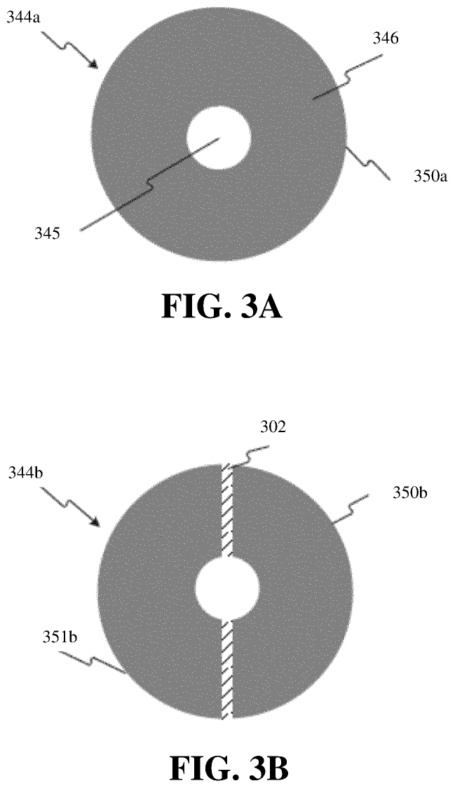

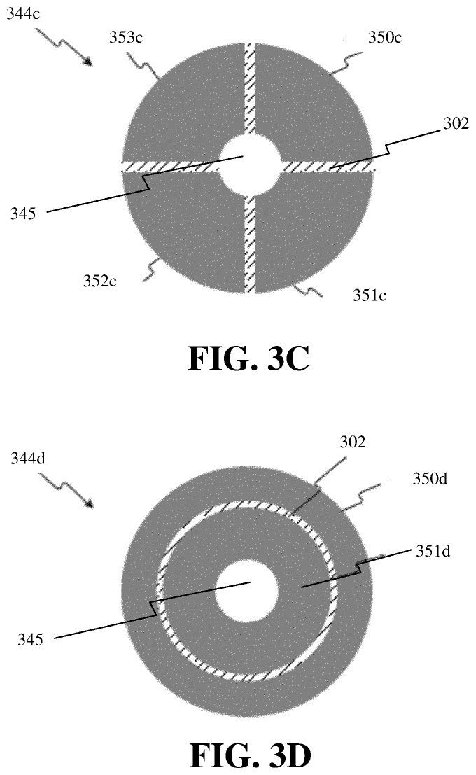

FIGS. 3A-D illustrate schematic diagrams of detectors 344a-d. Detectors 344a-d may comprise, e.g., electron detectors, other charged particle detectors, or photon detectors. Detectors 344a-d may comprise an aperture 345 configured to allow a primary electron beam to pass through the detector and be incident on a sample surface. Alternatively, the detectors 344a-d may be configured to be located away from a primary beam axis and may not comprise an aperture 345. Detectors 345a-d may comprise a diode, such as a PIN diode, a scintillator, a radiation detector, and a solid-state detector, among other charged-particle sensing devices.

In some embodiments, detectors 344a-d may comprise a monolithic detector (e.g., detector 344a), or a segmented detector (e.g., detectors 344b-d). In a monolithic detector, as shown in FIG. 3A, electron detection surface 346 may comprise a continuous layer of charged-particle sensitive material, forming a single segment 350a that corresponds to a single imaging channel. Detector 344a may be placed in a charged-particle beam apparatus (e.g., a single beam apparatus) such that the central axis of aperture 345 may align with a beam axis of a primary electron beam.

In some embodiments, segmented detectors may comprise two or more segments. In a segmented detector, such as shown in FIG. 3B, an electron detection surface 346 may comprise a discontinuous layer of charged-particle sensitive material, separated by a non-sensitive material 302 such as, e.g, a substrate material of detector 344b. Thus, the discontinuous layer may be divided into segments 350b and 351b. Each segment 350b and 351b may form a separate imaging channel and be coupled to a separate detection output (not shown). Segmented detectors 344b-d such as shown in FIGS. 3B-D, respectively, may be cylindrical with a circular, elliptical, or polygonal cross-section. One or more segments of segmented detectors may be arranged radially, circumferentially, or azimuthally in a symmetrical manner around a beam axis of a primary electron beam. The charged-particle sensitive material may be sensitive to charged particles such as electrons. Alternatively, detectors 344a-d may be configured to detect charged particles other than electrons, such as, e.g., protons. Further, the detectors 344a-d may be configured to detect photons instead of charged particles, such as light in the IR, visible, UV, DUV, EUV, x-ray, or any other wavelength range.

In some embodiments, segmented detectors may comprise more than two segments. For example, segmented detector 344c of FIG. 3C may comprise four segments 350c, 351c, 352c, and 353c, arranged circumferentially around a central aperture 345. The four segments may be separated by a non-sensitive material 302, such as a substrate from which detector 344c is made. Each segment 350c, 351c, 352c, and 353c may form a separate imaging channel and be coupled to a separate detection output. Therefore, segmented detector 344c may represent a four-channel detector.

In some embodiments, segmented detectors may comprise, e.g., two or more segments arranged concentrically. For example, segmented detector 344d of FIG. 3D may comprise two segments 350d and 351d arranged around the central aperture 345. Segmented detector 344d may represent a two-channel detector having a different geometry than two-channel detector 344b. The two segments may be separated by a non-sensitive material 302, such as a substrate from which detector 344d is made. Each segment 350d and 351d may form a separate imaging channel and be coupled to a separate detection output. Alternatively, detector 344d may comprise more than two concentric imaging channels. For example, detector 344d may comprise three, four, five or more concentric imaging channels.

Further information about monolithic and segmented detectors may be found in U.S. Patent Publication No. 2021/0319977, which is incorporated herein by reference in its entirety.

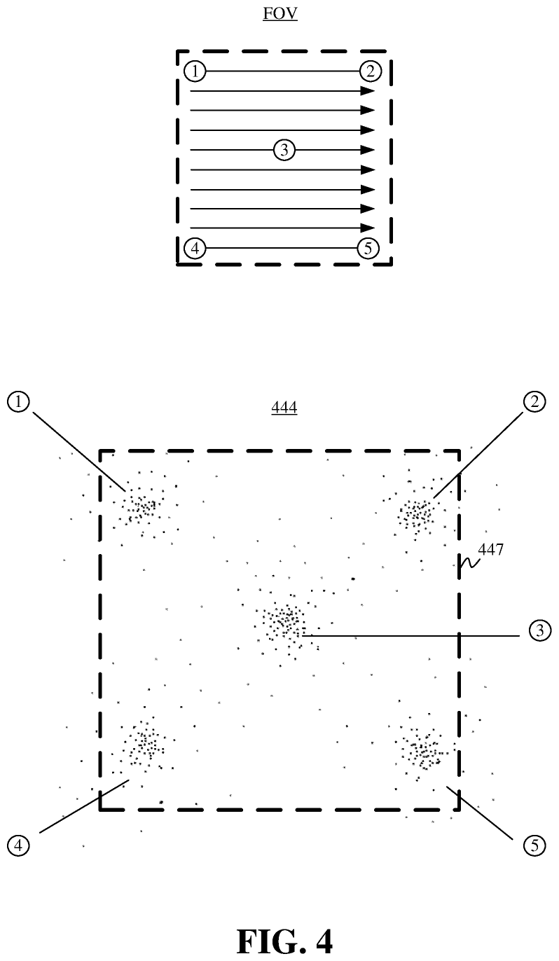

FIG. 4 illustrates an exemplary relationship between the probe spot of a primary beam scan in a field of view FOV of a sample and the corresponding distribution of electron landing positions on a region 447 of a detector 444. As illustrated by the horizontal arrows in the FOV of FIG. 4, a primary beam may be deflected to scan a probe spot along, e.g., a series of parallel scan lines. While the field of view FOV shows a traditional raster scan profile, it is appreciated that other scanning profiles can be used, such as a traditional or modified snake scan or a modified raster scan profile, among others.

Each discrete position at which the probe spot is scanned may generate emitted electrons, such as secondary or backscattered electrons, which may be incident on detector 444 as a cluster of electron landing positions. In some embodiments, each individual cluster of electron landing positions may represent, e.g. one pixel in a generated image. Thus, the corresponding spot on the sample surface may be called a sample pixel.

In FIG. 4, five such sample pixels 1-5 are depicted in the FOV along with their corresponding electron landing position clusters in region 447 of detector 444. The number and size of the depicted sample pixels are given for illustrative purposes only. For example, the FOV may be substantially covered by such sample pixels, and the detector surface near region 447 may be substantially covered with overlapping electron landing position clusters. When a probe spot irradiates an upper-left corner at location 1 in the FOV, a cluster of electron landing positions may be centered in a corresponding corner at location 1 of the region 447. The same applies to locations 2, 4, and 5. When a probe spot irradiates central position at location 3 in the FOV, a cluster of electron landing positions may be centered at location 3 of the region 447. In this way the scan of, e.g., a square-shaped FOV on a sample surface may produce a roughly square-shaped distribution of electron landing positions on a detector. It should be understood that the actual spatial relationship may vary from the schematic depiction shown. For example, the cluster of electron landing positions that are traced out on the region 447 may be, e.g., inverted, diagonally opposite, etc. from their corresponding probe spots in the FOV.

The landing positions of emitted electrons may be substantially clustered within a region having a radius of, for example, one or a few millimeters or more. In addition to a center location varying with the deflection angle of a primary beam, other parameters may affect a distribution of electron landing positions. For example, a geometric spread of landing positions of emitted electrons may vary as a result of the electrons having different trajectories due to, e.g., the initial kinetic energy and emission angles of the electrons. Additionally, a central location and geometric spread of a cluster of electron landing positions on the detector surface may vary based on conditions of the charged particle beam apparatus (such as charged particle beam apparatus 100A, 100B, or 100C of FIGS. 2A-C). For example, a higher landing energy may result in a greater divergence of emitted electrons, resulting in a larger geometric spread on a surface of detector 444.

As seen in FIG. 4, the size, shape, and location of a region on a detector surface that receives electrons may be related to the size, shape, and relative location of the FOV on the sample surface, as well as on conditions of the charged particle beam apparatus. Thus, for a given FOV exposure, not all of a detector surface may be needed. In conventional detectors (such as, e.g., detectors 344a-d of FIGS. 3A-D above), the size of a utilized detection surface may remain fixed even when charged particle beam process parameters (such as FOV size, landing energy, aperture size, beam current, lens/deflector settings, image compensation unit (ICU) tilt angle settings, etc.) are changed.

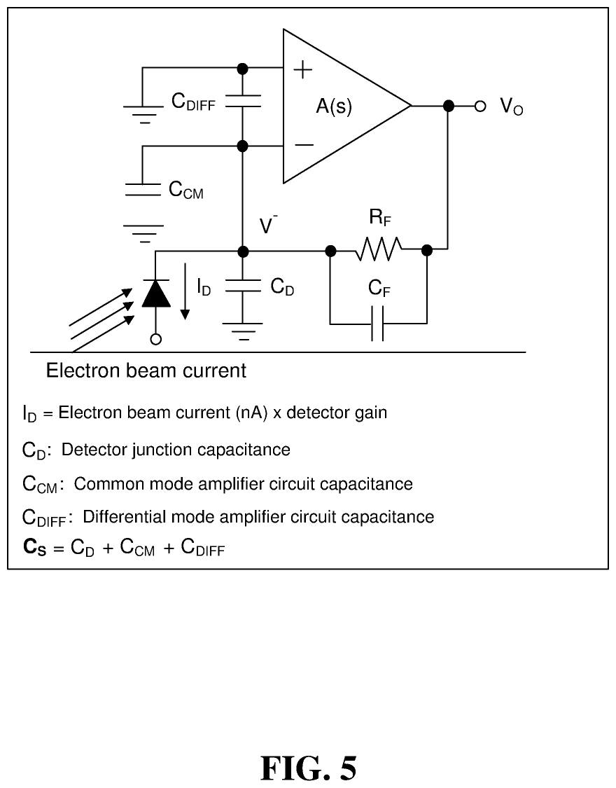

Using such a large detection surface may allow for high electron collection and easier alignment, but it may also result in reduced detection sensitivity and higher noise. For example, detector noise may be increased by parasitic capacitance within the detection system. FIG. 5 shows an exemplary circuit diagram illustrating various elements that may contribute to noise in a single imaging channel of a charged particle detector. For example, in a monolithic detector, the circuit diagram may represent noise of the entire detector. In a two-channel detector such as, e.g., detector 344b of FIG. 3B, the circuit diagram may represent noise from one semi-circular imaging channel 350b or 351b. Noise i_{EQ} may be represented by:

$${i}_{EQ} = \sqrt{{i}_{B}^{2} + \frac{4 k T}{{R}_{F}} + {( \frac{{e}_{N}}{{R}_{F}} )}^{2} + \frac{{( {e}_{N} 2 π F {C}_{S} )}^{2}}{3}} \qquad ( eqn . 1 )$$

where i_{B} is the electron beam shot noise,

$$\frac{4 k T}{{R}_{F}}$$

represents thermal noise by a feedback transistor,

$$\frac{{e}_{N}}{{R}_{F}}$$

is the reference voltage noise in a pre-amp non-inverting point, and

$$\frac{{( {e}_{N} 2 π F {C}_{S} )}^{2}}{3}$$

represents capacitance-induced noise in the image channel. Within this final term, capacitance C_{S} may comprise multiple components such as common mode amplifier circuit capacitance C_{CM}, differential mode amplifier circuit capacitance C_{DIFF}, and detector junction capacitance C_{D}. Among these components, junction capacitance C_{D} may represent a large contribution to overall capacitance-induced noise. For instance, in an exemplary case in which common mode amplifier circuit capacitance C_{CM} and differential mode amplifier circuit capacitance C_{DIFF} each contribute approximately 20˜25 pF, junction capacitance C_{D} in a conventional single-channel detector may contribute, e.g., 150 pF or more.

The size of a detector surface may have a direct relationship with the total junction capacitance C_{D}. However, as discussed above, some detectors may have a fixed detection area even when the used area of the detector (e.g., the area upon which emitted electrons are incident) is changed. For example, a used area of the detector may change due to changes in FOV size, beam aperture settings, landing energy, lens/deflector settings, ICU tilt angle settings, or other parameters. Such detectors may therefore have a higher noise penalty that cannot be reduced even when, e.g., detecting small areas or using low landing energies. Furthermore, even if a detection area may be changed by, e.g., excluding at least one imaging channel of a multi-channel segmented detector, the detector segments may not have sizes, shapes or positions that correspond to the size, shape, or position of the FOV. Therefore, it may be difficult change the effective detection area while maintaining a high electron collection efficiency.

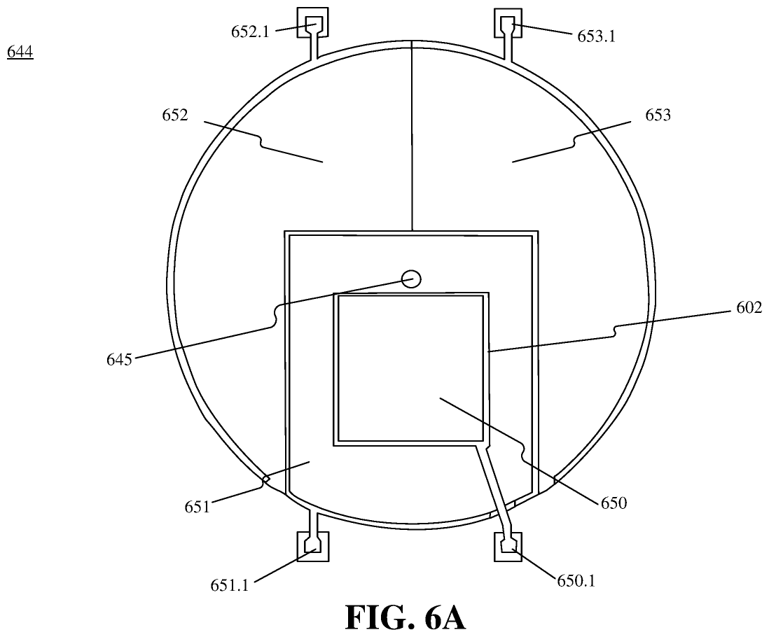

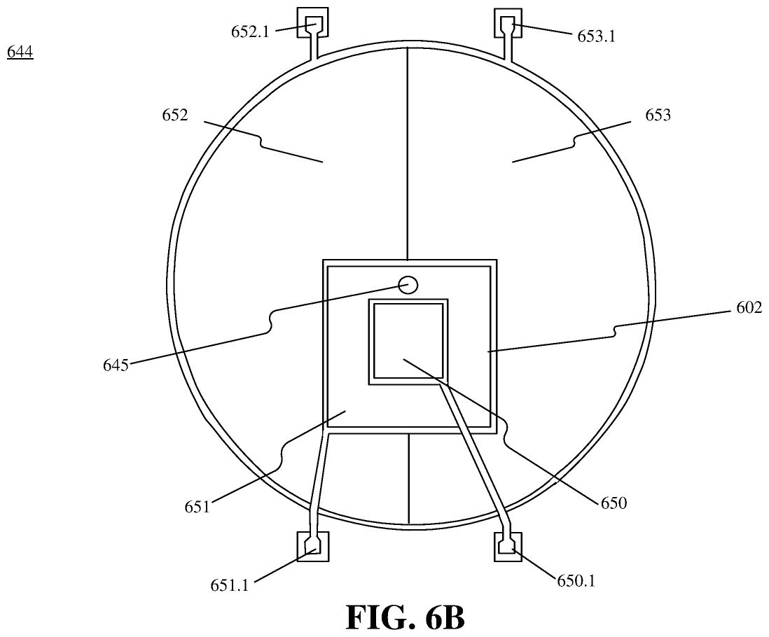

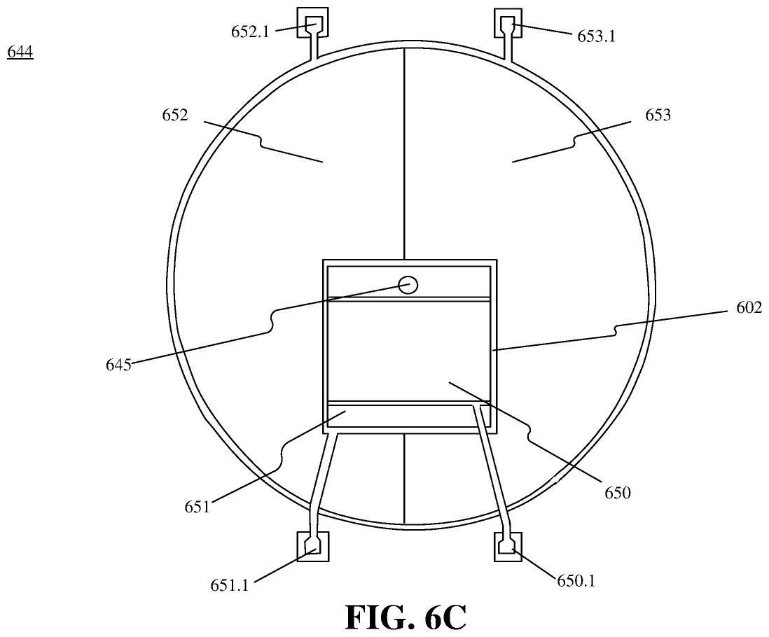

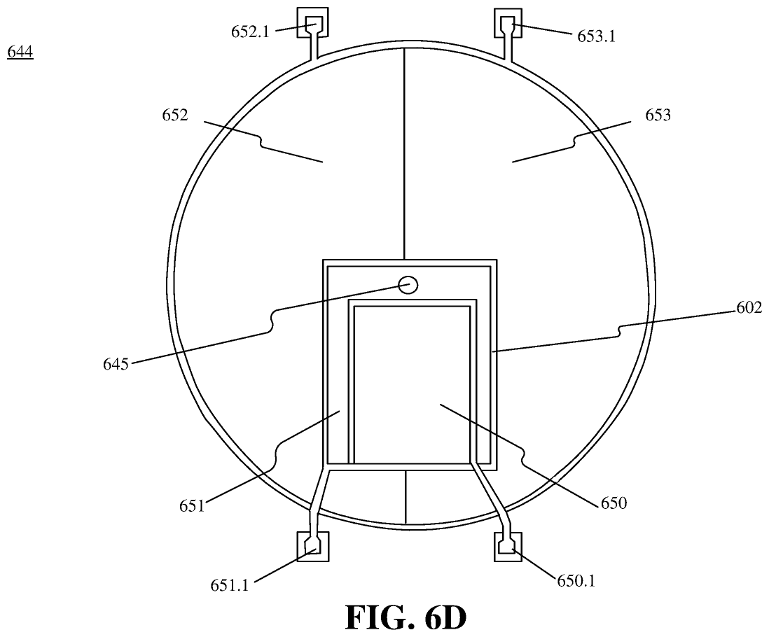

FIGS. 6A-D illustrate examples of a segmented charged particle detector 644, consistent with embodiments of the present disclosure. Charged particle detector 644 may be, e.g., an electron detector configured to be used in a SEM or other electron beam apparatus, such as an apparatus according to FIG. 1, 2A, 2B or 2C. Charged particle detector 644 may comprise a first segment 650, second segment 651, third segment 652, and fourth segment 653. First segment 650 may be coupled to a first detection output 650.1, second segment 651 may be coupled to a second detection output 651.1, third segment 652 may be coupled to a third detection output 652.1, and fourth segment 653 may be coupled to a fourth detection output 653.1. Charged particle detector 644 may comprise an aperture 645 configured to allow an electron beam (e.g., a primary electron beam or a beamlet) to pass through the detector and be incident on a sample surface. Alternatively, charged particle detector 644 may be configured to be located away from a primary beam axis and may not comprise an aperture 645.

As shown in FIG. 6A, first segment 650 may be offset from a center of detector 644 so that aperture 645 is positioned away from first segment 650. Charged particle detector 644 may comprise a diode, such as a PIN diode, a scintillator, a radiation detector, and a solid-state detector, among other charged-particle sensing devices. Segments 650-653 of charged particle detector 644 may be separated by a non-sensitive material 602.

A first detector region of detector 644 may comprise first segment 650. A second detector region may comprise first segment 650 as well as second segment 651, which may partially or completely surround first segment 650. For example, second segment 651 may completely surround first segment 650 as seen in FIG. 6A or 6B. Alternatively, second segment 651 may border first segment 650 on, e.g., two sides, for example as seen in FIG. 6C. Second segment 651 may surround, e.g., at least 50%, or at least 75%, of a border of first segment 650. For example, first segment 650 may be offset from a center of detector 644 such that a portion of first segment 650 substantially forms an outer boundary of the overall detector surface. In this case, second segment 651 may only border first segment 650 on two or three sides, and may therefore surround only approximately 50% or 75% of the border of first segment 650. As a further example, first segment 650 may border second segment 651 on a portion of its boundary and may border a further segment (such as third segment 652 or fourth segment 653) on a remainder of its boundary, for example as seen in FIG. 6D. In general, second segment 651 may be arranged to form the second detector region in combination with first segment 650.

The segments of detector 644 may be shaped so as to create detector regions that correspond to typical shapes of a FOV to be scanned. For example, for an apparatus that may scan, e.g., a rectangular or square-shaped FOV, the first detector region or the second detector may have rectangular-based shapes that correspond to the FOV shape. For example, the rectangular-based shape may be substantially square, substantially rectangular, or may be a shape that matches an expected electron distribution from a substantially square or substantially rectangular FOV. The first detector region or the second detector may have a shape with three flat sides and one curved side, as seen in the second detector region formed by the boundary of second segment 651 in FIG. 6A. Alternatively, the first detector region or the second detector may have all flat sides as seen in FIG. 6B. In some embodiments of the present disclosure, a side of the first segment may be, e.g., 1 mm, 2 mm, 3 mm, 4 mm, 5 mm, 6 mm, 7 mm, 8 mm, 9 mm or more. In some embodiments of the present disclosure, an outer side of the second segment may be, e.g., 3 mm, 4 mm, 5 mm, 6 mm, 7 mm, 8 mm, 9 mm, 10 mm, 12 mm, 15 mm or more. Other FOV shapes are possible. Therefore, in some embodiments of the present disclosure, other shapes of the first and second detector region are contemplated as well. In some embodiments, the shapes of segments or detector regions may be designed to match the shape of a charged particle landing distribution associated with the FOV rather than matching the shape of the FOV itself. As an example, if a square FOV is expected to produce a distribution that resembles a distorted square on a detector surface, such as by pincushion or barrel distortion, then the segments or detector regions may be shaped according to the pincushion- or barrel-distorted shape.

The first detector region may have lower noise than the second detector region. For example, because the first detector region may comprise only first segment 650, the first detector region may have a smaller surface area than the second detector region. This smaller surface area may result in a smaller junction capacitance C_{D} for the first detector region, which may lead to lower noise (such as a lower noise value i_{EQ} as discussed above at eqn. 1 and FIG. 5). Because the second region adds further junction capacitance from second segment 651, the second region may have a higher noise value than the first region. However, the added size of the second region may allow for greater electron collection.

Thus, detector 644 may allow a tradeoff to be selected between noise and collection rate, depending on the parameters of a particular charged particle beam exposure. A charged particle beam apparatus (such as, e.g., any of apparatus 100, 100A, 100B or 100C of FIGS. 1-2C) may scan a FOV on a sample surface and generate an image based on signals from, e.g., one of the first detector region and the second detector region. An image that is generated based on signals from the first detector region may have lower image channel noise, leading to a higher image accuracy. For example, signals from the first detector region may have a lower electrons root mean square (rms) value than signals from the second detector region. Alternatively, an image that is generated based on signals from the second detector region may be preferable in view of the higher available collection surface.

For example, a first charged particle beam exposure (such as an electron beam exposure in, e.g., in any of apparatus 100, 100A, 100B or 100C of FIGS. 1-2C), may comprise a first exposure parameter that results in a first portion of charged particle landing positions being contained within the first detector region on first segment 650. The first exposure parameter may comprise, e.g., a first FOV size on a sample surface, a first landing energy, a first beam aperture setting, a first beam current, a first lens/deflector setting, a first ICU tilt angle setting, or another parameter that may affect a distribution of charged particle landing positions on the surface of detector 644. The first portion may comprise, e.g. 90% or more of the charged particle landing positions on the detector. In some embodiments, the large portion may comprise, e.g., 95%, 99%, 99.5%, 99.9%, or 99.99% of charged particle landing positions on the detector. The first charged particle beam exposure may comprise a first noise value in the first detector region.

A second charged particle beam exposure may comprise a second exposure parameter that results in a second portion of charged particle landing positions being contained within the second detector region on first segment 650 and second segment 651. The first and second exposure parameters may comprise, e.g., different values of the same parameter. For example, the first exposure parameter may comprise a first FOV size, and the second parameter may comprise a second FOV size that is larger than the first FOV size. The second charged particle beam exposure may comprise a second noise value in the second detector region. The second noise value may be higher than the first noise value.

In some embodiments, the first charged particle beam exposure and the second charged particle beam may not be performed simultaneously. In some embodiments, the first and second portions of charged particle landing positions may be, e.g., substantially equal. For example, a first charged particle beam exposure may comprise a first FOV size on a sample surface. The first FOV size may result in a first portion, e.g., >95%, of charged particle landing positions being contained within the first detector region on first segment 650. A second charged particle beam exposure may comprise a second FOV size on a sample surface that is larger than the first FOV size. The second FOV size may result in a second portion, e.g., also >95%, of charged particle landing positions being contained within the second detector region on first segment 650 and second segment 651. Alternatively, the second portion may be larger than the first portion.

In some embodiments, the first charged particle beam exposure and the second charged particle beam may be performed simultaneously. In some embodiments, the first and second portions of charged particle landing positions may be different. For example, a charged particle beam exposure may comprise a first portion, e.g., >95%, of charged particle landing positions being contained within the first detector region on first segment 650, and a second portion, e.g., >99%, of charged particle landing positions being contained within the second detector region on first segment 650 and second segment 651. The charged particle beam exposure may comprise a first noise level in the first detector region and a second noise level in the second detector region. In some embodiments, an operator may utilize a first detection signal from the first detector region in view of, e.g., a lower noise value in the first detector region. In some embodiments, an operator may utilize a second detection signal from the second detector region in view of, e.g., a higher collection rate in the second detector region. The second signal may comprise the first detection signal from first segment 650 as well as a further detection signal from second segment 651. In some embodiments, the second detection signal may comprise a weighted average or other mathematical combination of the first detection signal and the further detection signal.

The first detection signal from the first detector region may be used to generate a first image of a sample having a first accuracy. The second detection signal from the second detector region may be used to generate a second image of a sample having a second accuracy. The first accuracy may be higher than the second accuracy.

Charged particle detector 644 may comprise further detector regions. For example, charged particle detector may comprise a third detector region corresponding to third segment 652 and a fourth detector region corresponding to fourth segment 653. In some embodiments, signals form the third and fourth detector regions may be used for, e.g., monitoring beam alignment. In some embodiments, charged particle detector may comprise a fifth detector region comprising all four segments. For example, the fifth detector region may be used for optimal collection of charged particle landing positions on the detector surface.

While FIGS. 6A-D illustrate four segments 650-653, embodiments of the present disclosure are not limited to this. For instance, a detector surface may comprise more than two nested detector segments, yielding a greater number of selectable detector regions. For example, there may be a smaller segment located within first segment 650, or a larger detector segment that is surrounding second segment 651 and, e.g., located between second segment 651 and third and fourth segments 652-653.

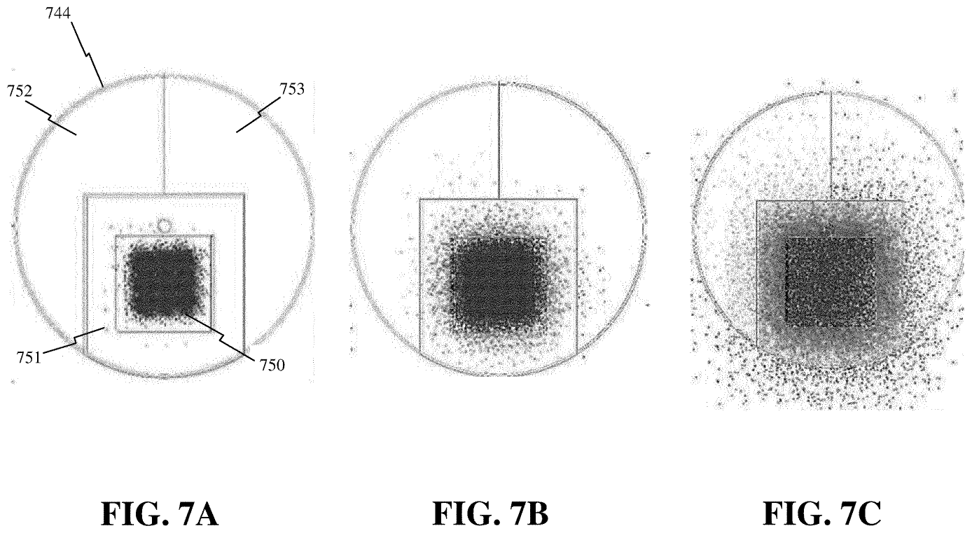

FIGS. 7A-C illustrate example distributions of charged particle landing positions on a detector 744, consistent with embodiments of the present disclosure. Detector 744 may be, e.g., detector 644 of FIGS. 6A-D. As seen in FIG. 7A (corresponding labels omitted in FIGS. 7B-C), detector 744 may comprise, e.g., four segments 750-753, similar to detector 644 of FIGS. 6A-D.

FIG. 7A illustrates a first distribution of charged particle landing positions. The first distribution may correspond to, e.g., a first charged particle beam exposure comprising a first value of an exposure parameter. The exposure parameter may comprise, e.g., FOV size, beam aperture setting, landing energy, a lens/deflector setting, an ICU tilt angle setting, or another parameter. Similarly, FIGS. 7B and 7C may illustrate second and third distributions, respectively, of charged particle landing positions corresponding to second and third charged particle beam exposures comprising second and third values of the exposure parameter. For example, the distributions of FIGS. 7A-C may correspond to three distributions of charged particle landing positions at low, medium, and high landing energy settings, respectively. As seen in FIG. 7A, a first detector region comprising segment 750 may capture a larger portion of charged particle landing positions at the low landing energy setting. Therefore, the first detector region, having lower noise, may be ideal for use with the first exposure. In FIG. 7B, the first detector region may not capture a sufficient portion of charged particle landing positions at the medium landing energy setting. However, a second detector region comprising first segment 750 and second segment 751 may capture a sufficient portion at a higher noise penalty. Thus, one of the first detector region and the second detector region may be ideal for use with the second exposure. For example, the first detector region may be preferred for lower noise, or the second detector region may be preferred for a higher collection rate. In FIG. 7C, at the higher landing energy setting, there may be a significant distribution of electrons outside the second detector region. In this case, the second detector region may strike the appropriate balance between noise and collection rate. Alternatively, a larger detector region may be employed, such as a fifth detector region as discussed above, comprising all four segments of detector 744.

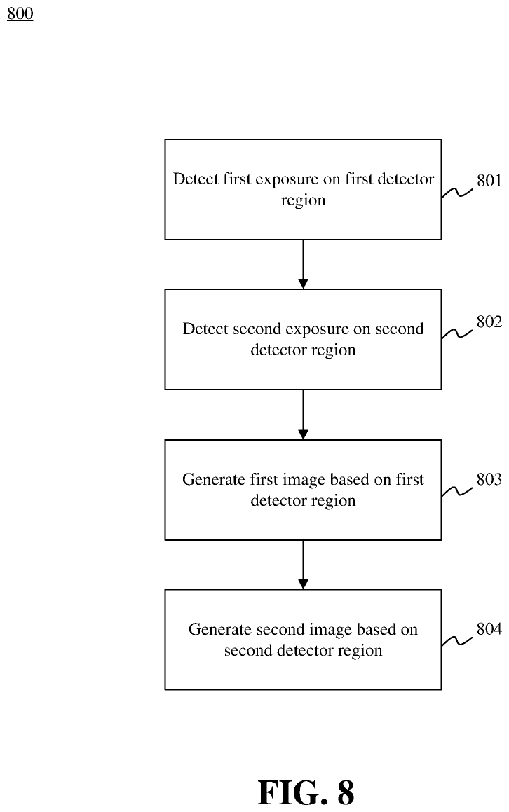

FIG. 8 is a flowchart illustrating a charged particle detection method 800, consistent with embodiments of the present disclosure. Method 800 may be performed using a charged particle beam apparatus, such as electron beam tool 100, 100A, 100B, or 100C of FIGS. 1-2C. A charged particle detector, such as detector 644 of FIGS. 6A-D or 744 of FIGS. 7A-C, may be operated in accordance with method 800. The method may be performed by a controller (such as controller 109 or image processing system 199).

At step 801, a first exposure may be detected on a first detector region of a detector. The first exposure may comprise a charged particle beam process in which a primary charged particle beam exposes the surface of a sample, generating emitted charged particles from the sample which are detected at the detector surface to generate a first signal. For example, the first exposure may comprise a SEM scan or other electron beam tool process. The first exposure may be performed under a first exposure setting. For example, the first exposure setting may comprise a first FOV size, a first landing energy, a first beam aperture setting, a first beam current, a first lens/deflector setting, a first ICU tilt angle setting, or another parameter that may affect a distribution of charged particle landing positions on the surface of the detector. The first detector region may comprise, e.g., a first segment of a segmented charged particle. The first detector region may comprise a first noise parameter. For example, the first noise parameter may comprise a capacitance value of the first segment, such as a junction capacitance.

At step 802, a second exposure may be detected on a second detector region of the detector. The second exposure may comprise, e.g., a process similar to the first exposure, which may be detected at the second detector region to generate a second signal. The second exposure may be performed under a second exposure setting. For example, the second exposure setting may comprise a second FOV size, a second landing energy, a second beam aperture setting, a second beam current, a second lens/deflector setting, a second ICU tilt angle setting, or another parameter that may affect a distribution of charged particle landing positions on the surface of the detector. In some embodiments, the second exposure may be performed under the first exposure setting.

The first exposure and the second exposure may occur concurrently or at different times. For example, the first exposure and the second exposure may comprise a singular scan, in which the first exposure refers to the portion of the scan occurring over a first smaller FOV, and the second exposure refers to the portion of the scan occurring over a second larger FOV. The first FOV and the second FOV may overlap. Alternatively, the first FOV and the second FOV may be located on different portions of the same or a different sample surface.

The second detector region may comprise, e.g., the first segment as well as a second segment of the segmented charged particle detector. The second segment may be arranged to form the second detector region in combination with the first segment. In some embodiments, the second segment may surround the first segment. The second detector region may comprise a second noise parameter. For example, the second noise parameter may comprise a capacitance value of the first segment and the second segment, such as a junction capacitance.

At steps 803 and 804, first and second images may be generated based on the first and second signals detected at the first and second detector regions, respectively. The first image may have a higher accuracy than the second image. For example, the first signal may have a lower SNR ratio in view of, e.g., a lower junction capacitance in the first detector region than the second detector region. The second image may alternatively be preferred in view of a higher collection rate of charged particles on the surface of the second detector region. A composite image may be generated based on the first image and the second image. In some embodiments, the second image may provide baseline information for monitoring the first image. For example, because the first detector region is relatively small, misalignment may cause fewer charged particles to be incident on the first detector region, resulting in a degraded first image. The second image may be utilized to monitor or correct for this.

Method 800 may be used to generate an optimal image in each FOV of a sample surface. The method may be used to generate an optimal image of a full scan of the sample surface. The full scan may comprise, e.g., a composite of first images from the first detector region and second images form the second detector region.

Further images may be generated according to method 800 concurrently with the generation of the first and second images. For example, a full detector surface (such as with segments 650-653) may be used to generate an image at a maximum collection rate.

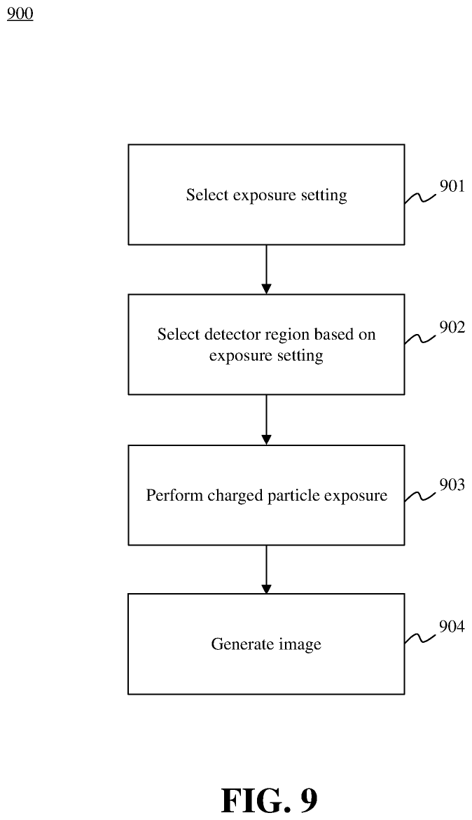

FIG. 9 is a flowchart illustrating a charged particle detection method 900, consistent with embodiments of the present disclosure. Method 900 may be performed using a charged particle beam apparatus, such as electron beam tool 100, 100A, 100B, or 100C of FIGS. 1-2C. A charged particle detector, such as detector 644 of FIGS. 6A-D or 744 of FIGS. 7A-C, may be operated in accordance with method 900. The method may be performed by a controller (such as controller 109 or image processing system 199).

At step 901, an exposure setting may be selected for a charged particle beam exposure process. The exposure process may an electron beam exposure or other charged particle exposure in, e.g., in any of apparatus 100, 100A, 100B or 100C of FIGS. 1-2C. The apparatus may further comprise a charged particle detector having first and second detector regions. For example, the detector may be, e.g., detector 644 of FIGS. 6A-D or detector 744 of FIGS. 7A-C. The exposure setting may comprise a parameter that affects a spatial distribution of charged particles arriving at the detector surface. For example, the parameter may include a FOV size, a landing energy, aperture size, beam current, lens/deflector setting, ICU tilt angle setting, or another parameter that affects the spatial distribution. The exposure setting may be an adjustable parameter or a fixed parameter. In the latter case, the step of selecting the exposure setting may take place at the time of design of the exposure apparatus.

At step 902, a detector region of the detector may be selected based on the exposure setting selected in step 901. For example, it may be determined that, based on the selected exposure setting, a sufficient portion of emitted charged particles (e.g., a predetermined percentage such as 90%, 95%, 99%, 99.5%, 99.9%, or 99.99%) from the sample surface will be collected at a first detector region. In this case, the first detector region may be selected for imaging. Alternatively, it may be determined that a higher collection rate may be needed. In this case, a second detector region may be selected. The second detector region may comprise the first detector region and a further region outside the first detector region.

At step 903, a charged particle exposure process may be performed using an apparatus as discussed at step 901. The charged particle exposure process may comprise the selected exposure setting. Detection may be performed at the selected detector region as discussed at step 902 to generate detection signal at the selected detector region. The detection may generate detection a signal having a preferred balance between SNR and collection rate.

At step 904, an image may be generated based on detection signals from the detector. The image may have a higher accuracy than an image that could be generated, for the given exposure setting, based on signals from another detector region of the detector.

The steps illustrated above in methods 800 and 900 are not necessarily performed in the order presented, and may be performed concurrently, or in orders other than what is presented above. By way of example, step 802 may be performed before or concurrently with step 801. Step 902 may be performed after or concurrently with steps 903 or 904.

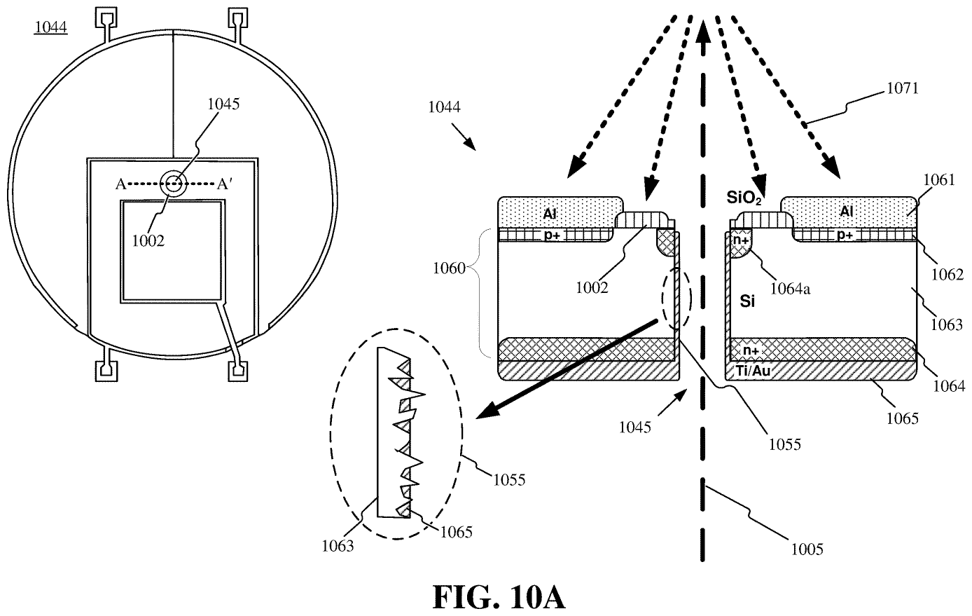

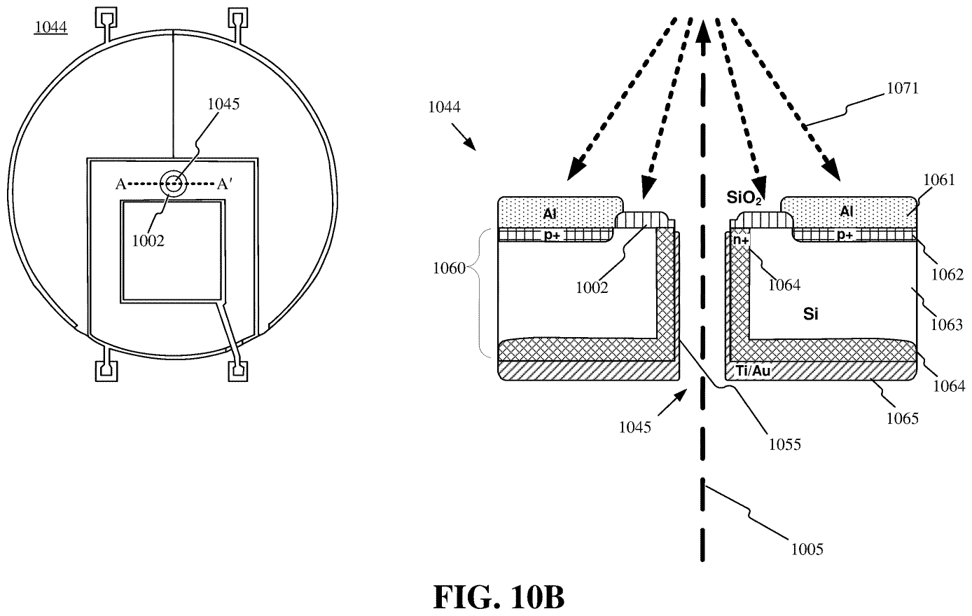

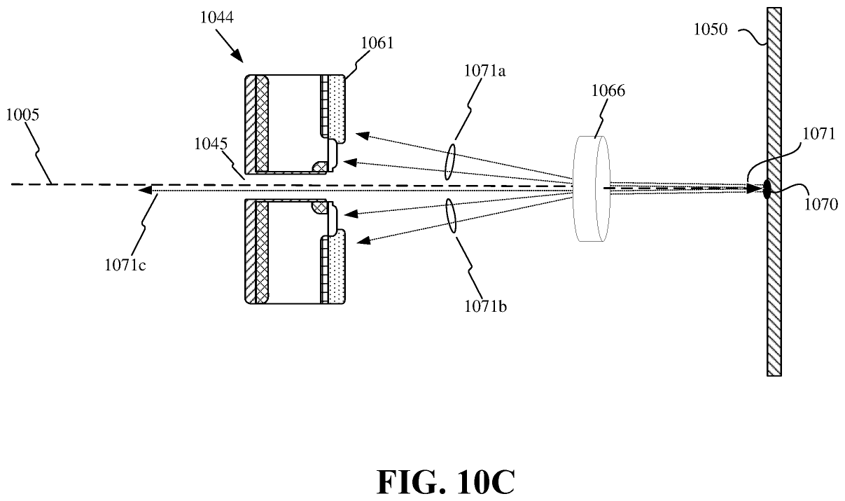

FIGS. 10A-C illustrate cross-sectional views of a portion of a charged particle detector 1044, according to some embodiments of the present disclosure. Charged particle detector 1044 may be, e.g., an electron detector configured to be used in a SEM or other electron beam apparatus, such as an apparatus according to FIGS. 1-2C. As illustrated at the left side of FIG. 10A, charged particle detector 1044 may comprise a segmented detector as discussed with respect to FIGS. 6A-D above. Detector 1044 may comprise, e.g., a PIN diode-type charged particle detector. Detector 1044 may be, e.g., about 20 millimeters (mm) in diameter. Detector 1044 may comprise an aperture 1045 having a diameter of about, e.g., between 2-4 mm, through which a primary charged particle beam 1005 passes (such as, e.g., 145 in FIG. 2C or 645 in FIGS. 6A-D).

As shown in FIG. 10A, detector 1044 may comprise a top conductive layer 1061 at a front surface (e.g., a surface facing the sample and configured to receive emitted charged particles), and a bottom conductive layer 1065 on a back surface (i.e., a surface not facing the sample and not configured to receive emitted charged particles). Top conductive layer 1061 may comprise, e.g., an aluminum layer. Top conductive layer 1061 may improve series resistance as well as reflect any stray light (e.g., a light coming from a laser and scattered inside a column of the SEM system). Top conductive layer 1061 may be configured as an electron-incident surface. Top conductive layer 1061 may form a sensor surface of detector 1044. Top conductive layer 1601 may comprise a top electrode of detector 1044. Bottom conductive layer 1065 may comprise, e.g., a titanium-gold layer. For example, bottom conductive layer 1065 may comprise a bottom electrode of detector 1044.

Detector 1044 may comprise a semiconductor region 1060 between top conductive layer 1061 and bottom conductive layer 1065. Semiconductor region 1060 may comprise, e.g., a p+ region 1062, an intrinsic region 1063, and an n+ region 1064. Intrinsic region 1063 may comprise a silicon layer, and the p+ and n+ regions 1062 and 1064 may comprise p-doped and n-doped regions on the silicon. A p+ region may comprise a p-type dopant such as, e.g., boron. An n+ region may comprise an n-type dopant such as one or more of arsenic, phosphorus, or antimony. The p+ and n+ regions 1062 and 1064 may form the terminals of the PIN diode. Alternatively, the region 1062 may comprise an n+ region and region 1064 may comprise a p+ region.

In operation, detector 1044 may provide the function of generating electrical signals in response to a charged particle arrival event. Incoming charged particles, such as emitted electrons 1071 from a sample (such as sample 1050 in FIG. 10B), may pass through top conductive layer 1061 and may enter a depletion region in intrinsic region 1063. The incoming electrons may interact with the material of intrinsic region 1063 and may generate electron-hole charge carrier pairs. The electrons and holes of the generated electron-hole pairs may be guided by internal electric fields in detector 1044 toward the p+ region 1062 n+ region 1040 to be collected at the top and bottom electrodes, thereby generating current that is indicative of the charged particle arrival event.

A “dead area” or non-sensitive region 1002 may surround aperture 1045 at the front surface of detector 1044. Non-sensitive region 1002 may comprise, e.g., a layer of SiO₂, or another oxide or non-conductive material. One issue that has a direct impact on the performance of a charged particle detector is the spatial extent of the non-sensitive region 1002 around an aperture 1045. Ideally, this non-sensitive region 1002 should be as small as possible, since the emitted electron 1071 distribution may be heavily concentrated around the aperture 1045 in some cases (see, for example, a distribution of emitted electrons 171 around hole 145 in FIG. 2C). Thus, for the case that most emitted electrons arrive at the center of the detector 1044, the proportion of detected electrons decreases with increasing size of the non-sensitive region 1002. Therefore, it may be desirable to reduce as much as possible any “dead areas” in the detector 1044 to improve its overall efficiency or sensitivity. However, a limit to the reduction of this “dead area” is the lateral extent of the deep depletion region required for a fast detection response (due to, e.g., reduced junction capacitance). For example, it may be desirable if the depletion layer does not reach the surface or sidewalls 1055 abutting aperture 1045 to prevent a significant increase of the leakage current in the image channel of a detection segment nearest aperture 1045.

A further issue facing charged particle detectors is the buildup of electric charge on surfaces of the detector. For example, as seen in FIG. 10A, some high-energy emitted electrons 1071 may impinge upon non-conductive or low-conductivity surfaces, such as the non-sensitive region 1002 or sidewalls 1055. In some cases, the high energy electrons may cause more electrons to be emitted than are deposited, leading to a net positive charge buildup at the surfaces. This can increase noise in the image channels and create asymmetries in the electric field near the path of primary charged particle beam 1005, leading to beam shifts, image aberrations and other errors. To reduce these effects, charged particle detector 1044 may be provided with a conductive material layer along the sidewalls 1055 abutting aperture 1045. For example, the Ti/Au material of bottom conductive layer 1065 may be extended up the sidewalls 1055 to a further n+ region 1064a, to smooth out charge imbalances along the sidewalls 1055. However, a problem exists as illustrated in the closeup view of sidewalls 1055 in FIG. 10A. Due to the surface roughness of intrinsic region 1063 and imperfections in manufacturing, the bottom conductive layer 1065 may exhibit nonuniformities along the sidewalls 1055. This may result in thickness variations of the Ti/Au material, as well as exposed portions of intrinsic region 1063. Therefore, asymmetries in the electric field near the path of primary charged particle beam 1005 may persist. Additionally, the further n+ region 1064a may cause a high leakage current due to its proximity to p+ region 1060.

Another way to minimize the above issues, as shown in FIG. 10B, may comprise extending a doping profile of the n+ region 1064 from the back surface of detector 1044 along sidewalls 1055 up to the front surface at non-sensitive region 1002. While this may further reduce electric field asymmetries within the aperture 1045, it does not resolve the problem of leakage current. And it fails to address the charge buildup occurring at non-sensitive region 1002, or the corresponding reduction in efficiency and sensitivity. These issues may be especially problematic when an ICU is not in use.

For example, FIG. 10C schematically illustrates a relationship between a sample 1050, the cross-sectional portion of detector 1044, and an ICU 1066. ICU 1066 may be configured to impart a tilt angle to the emitted electrons 1071. ICU 1066 may comprise, e.g., a plurality of coils through which a high electrical current is generated. In this way, emitted electrons may be diverted away from a center of aperture 1045 so that more electrons land on a detection surface. For example, in the plane of FIG. 10C, ICU 1066 may divert first emitted electrons 1071a and second emitted electrons 1071b away from aperture 1045 such that a greater number of emitted electrons land on the detection surface of top conductive layer 1061. In the absence of ICU 1066, a majority of emitted electrons may be emitted with such low divergence that they pass directly back through the aperture 1045 (as illustrated by emitted electrons 171c), or a larger number of electrons may impinge on non-sensitive region 1002, greatly diminishing collection efficiency and increasing charge-induced noise. However, due to the fields created by the high currents within its coils, the ICU may generate noise and other aberrations of its own. Therefore, it may be desirable to eliminate the ICU while maximizing collection efficiency and minimizing noise and other charging effects.

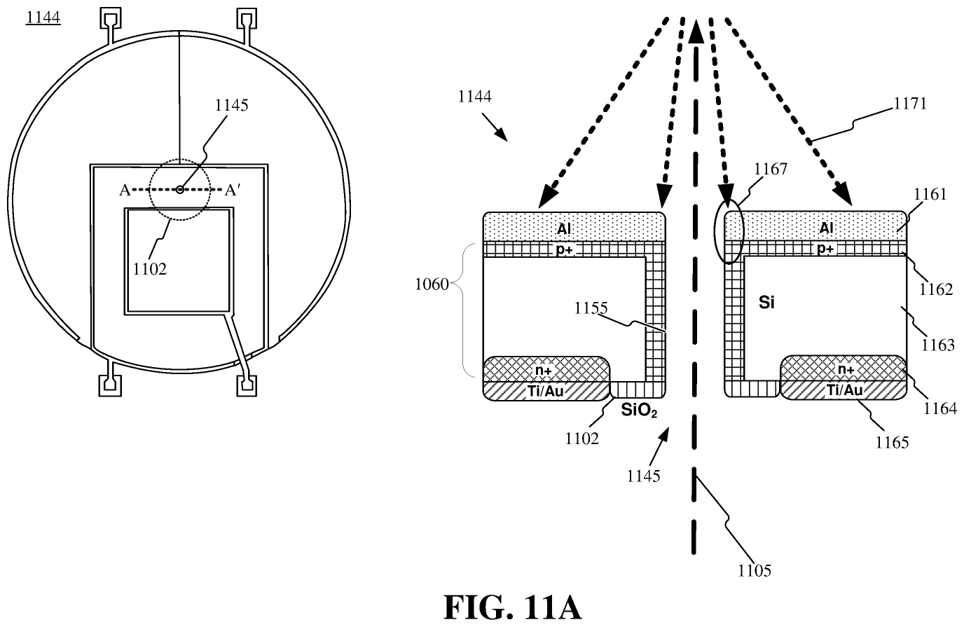

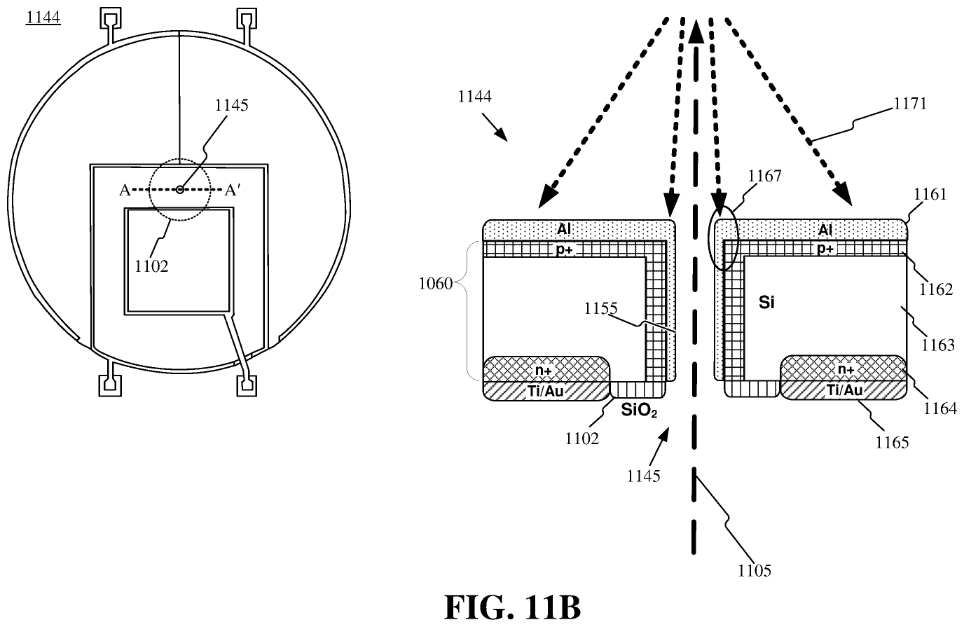

Embodiments of the present disclosure provide a charged particle detector capable of maximizing charged particle collection efficiency while minimizing unwanted charging effects. Charged particle detectors according to embodiments of the present disclosure may allow for the elimination of an ICU from a charged particle apparatus, further reducing noise and improving image quality. FIGS. 11A-B illustrate cross-sectional views of a portion of a charged particle detector 1144, consistent with embodiments of the present disclosure. Charged particle detector 1144 may be similar to, e.g., charged particle detector 1044, except as described below.

As shown in FIG. 11A, charged particle detector 1144 may comprise a top conductive layer 1161, semiconductor region 1160, bottom conductive layer 1165, and non-sensitive region 1102. Semiconductor region 1160 may comprise, e.g., a first doped region 1162, an intrinsic region 1163, and a second doped region 1164. As illustrated, first doped region 1162 may comprise a p+ region and a second doped region 1164 may comprise an n+ region. However, in some embodiments, first doped region 1162 may comprise an n+ region and second doped region 1164 may comprise a p+ region. In general, the first doped region 1162 may have a different conductivity type from the second doped region 1164. For example, if one doped region is an n-doped type such as, e.g., n, n+, or n++, the other doped region may be a p-doped type such as, e.g., a p, p+, or p++ type. First doped region 1162 may extend from a front (detection) surface of semiconductor region 1060 into sidewalls 1155 abutting an aperture 1145. First doped region 1162 may extend along the sidewalls 1155 abutting aperture 1145 to a non-sensitive region 1102 comprising, e.g., a layer of SiO₂ or other material as discussed above. Top conductive layer 1161 may extend to an edge 1167 of aperture 1145, as illustrated in FIG. 11A. Alternatively, as shown in FIG. 11B, top conductive layer 1161 may extend along the sidewalls 1155 abutting aperture 1145 to improve series resistance there. Using the arrangement of FIG. 11A or 11B, the “dead area” required to maintain a large depletion region between first doped region 1162 and second doped region 1164 may be achieved at a back (non-detection) surface of detector 1144. For example, non-sensitive region 1102 may extend from first doped region 1162 and may contact at least one of second doped region 1164 or bottom conductive layer 1165. The arrangements of FIGS. 11A-B may yield numerous advantages to collection efficiency, detector speed, imaging performance, and noise reduction.

For example, by relocating the non-sensitive region 1102 to a back surface, the detection surface on a front side of the detector 1144 may be increased in precisely the area that may receive the highest concentration of emitted electrons 1171, thereby greatly improving collection efficiency. For example, as seen in FIGS. 11A-B, the detection surface may extend to the edge 1167 of aperture 1145 itself, such as an entire perimeter of the edge 1167 of aperture 1145. Thus, within the central region of detector 1144, electrons that are emitted to any portion of the front surface may be collected. At the same time, charging errors may be reduced in view of the fact that non-sensitive region 1102 is not irradiated. Therefore, moving the non-sensitive region 1102 to a back surface not only increases collection efficiency, but it reduces noise, beam shifts and other charging effects.

Furthermore, collection efficiency may be improved in view of the first doped region 1162 being extended along sidewalls 1155 abutting aperture 1145. This creates a further detection surface on the sidewalls 1155. Therefore, even emitted electrons 1171 that pass into aperture 1145 may be collected if they impinge on the sidewalls 1155. At the same time, the doped surfaces of sidewalls 1155 may serve a function of preventing charge buildup, so that asymmetries in the electric field may be reduced. Thus, beam shifts, aberrations and other imaging errors may further be improved while collection efficiency is further increased.

In some embodiments, the detection area may be further increased by shrinking the diameter of aperture 1145 as compared to, e.g., aperture 1045 of FIGS. 10A-C. For example, while aperture 1045 may have a diameter of, e.g., 2-4 mm, aperture 1145 may have a diameter of, e.g., 200-400 μm. This feature may also serve several purposes. First, as mentioned already, the effective detection surface area on a front surface of detector 1144 may be increased by shrinking the aperture diameter. Second, the reduced aperture diameter, as well as the addition of sidewall detection surfaces, may render an ICU unnecessary. For example, it may no longer be required to tilt the emitted electrons 1171 away from the center of detector 1144 because relatively few emitted electrons will enter the aperture 1145, and even fewer will exit. Instead, most emitted electrons 1171 may be received either at the front surface of top conductive layer 1161, or on the sidewalls 1155. Therefore, the ICU may be discarded, eliminating a strong source of noise.

The shrinking of aperture 1145, and the relocation of non-sensitive region 1102, each provide additional degrees of freedom in optimizing a lateral extent of a depletion region between first doped region 1162 and second doped region 1164. This can be most easily appreciated by comparing the bird's eye view of detector 1044 on the left in FIGS. 10A-B to the bird's eye view of detector 1144 on the left in FIGS. 11A-B. In detector 1044, design of the outer diameter of non-sensitive region 1002 may be constrained by the need to maintain a small dead area. Meanwhile, design of the inner diameter of non-sensitive region 1002 may be constrained by the need to provide a sufficiently large aperture size to minimize the effects of electric field asymmetries on primary charged particle beam 1005. Therefore, the maximum size of a depletion region between further n+ region 1064a and p+ region 1062 is limited. This may lead to increased junction capacitance, a slower detection response and higher leakage current. However, the non-sensitive region 1102 in detector 1144 is not so limited. For example, as discussed above, by providing first doped region 1162 along sidewalls 1155, a diameter of aperture 1145 may be reduced without introducing unacceptable asymmetries in an electric field at primary charged particle beam 1105. Thus the separation distance between the first doped region and second doped region may be increased even for a non-sensitive region 1102 of the exact same diameter as that of non-sensitive region 1002. However, because the non-sensitive region 1102 is located on a back surface of detector 1144, its size may be increased without a loss of detection surface area or an increase in charging effects. Further, as seen in FIGS. 11A-B, the non-sensitive region 1102 could overlap other top-side boundaries, such as by crossing over adjacent detector segments, without any substantial design complications. Therefore a non-sensitive region 1102 may be made larger to achieve a reduced junction capacitance, a faster detection response, and smaller leakage currents. For example, even when an aperture 1145 is, e.g., between 200 μm and 1 mm in diameter, a non-sensitive region 1102 may have an outer diameter of, e.g., 4, 6, or 8 mm.

Further, while the cross-sectional structures in the neighborhood of a detector aperture have been disclosed with respect to the segmented detectors of, e.g., FIGS. 6A-D, embodiments of the present disclosure are not limited to this. For example, in some embodiments, the cross-sectional configurations of FIGS. 10A-11B may be arranged in other detectors, such as monolithic or segmented surface detectors of the types illustrated at FIGS. 3A-D, a pixelated array of segments, or other detector arrangements.

Embodiments of the present disclosure may further be described using the following clauses:
1. A segmented multi-channel detector, comprising:
   a first detector region having a first segment; and
   a second detector region having the first segment and a second segment, the second segment surrounding at least 50% of the first segment, wherein
   the first detector region comprises a first noise value of a noise parameter; and
   the second detector region comprises a second noise value of the noise parameter, the second noise value being higher than the first noise value.
2. The segmented multi-channel detector of clause 1, wherein the noise parameter is capacitance.
3. The segmented multi-channel detector of clause 1, wherein the noise parameter is junction capacitance.
4. The segmented multi-channel detector of clause 1, wherein the second segment completely surrounds the first segment.
5. The segmented multi-channel detector of clause 1, wherein the first segment has a rectangular-based shape.
6. The segmented multi-channel detector of clause 4, wherein the rectangular-based shape is a square-based shape.
7. The segmented multi-channel detector of clause 1, wherein the first segment has a dimension in a first direction of at least 1 mm.
8. The segmented multi-channel detector of clause 1, wherein:
   a shape of the first detector region corresponds to a shape of a first FOV on a sample surface in a charged particle beam apparatus.
9. The segmented multi-channel detector of clause 8, wherein:
   a shape of the second detector region corresponds to a shape of a second FOV on the sample surface in the charged particle beam apparatus, the second FOV being larger than the first FOV.
10. The segmented multi-channel detector of clause 1, further comprising:
   a third segment bordering at least a first side of the second detector region; and
   a fourth segment bordering at least a second side of the second detector region, the second side being opposite the first side.
11. The segmented multi-channel detector of clause 1, further comprising an aperture located outside the first segment.
12. The segmented multi-channel detector of clause 9, wherein the aperture is located in the second segment.
13. A charged particle beam apparatus, comprising:
   a charged particle beam source configured to generate a beam of primary charged particles;
   a charged particle optical system configured to scan the beam of primary charged particles over a field of view (FOV) of the sample surface; and
   the segmented multi-channel detector of clause 1.
14. The charged particle beam apparatus of clause 13, wherein:
   a shape of the first detector region corresponds to a shape of the FOV on the sample surface.
15. The charged particle beam apparatus of clause 13, wherein:
   a shape of the second detector region corresponds to a shape of the FOV on the sample surface.
16. The charged particle beam apparatus of clause 13, wherein:
   the first detector region is configured to capture more than 90% of emitted charged particles from the scan of the beam over the FOV of the sample surface.
17. The charged particle beam apparatus of clause 13, wherein:
   the second detector region is configured to capture more than 90% of emitted charged particles from the scan of the beam over the FOV of the sample surface.
18. A method of detecting a charged particle event in a charged particle detector, comprising:
   performing a first scan of a sample surface with a charged particle beam under a first exposure setting to cause emitted charged particles from the sample surface to land in a first detector region of the charged particle detector, the first detector region comprising a first noise value of a noise parameter;
   generating a first image based on the first scan;
   performing a second scan of the sample surface with a charged particle beam under a second exposure setting to cause emitted charged particles from the sample surface to land in a second detector region of the charged particle detector, the second detector region comprising a second noise value of a noise parameter, the second noise value being higher than the first noise value; and
   generating a second image based on the second scan, the first image having a higher accuracy than the second image, wherein
   the first detector region comprises a first segment of the charged particle detector;
   the second detector region comprises the first segment and a second segment of the charged particle detector; and
   the second detector region is larger than the first detector region.
19. The method of clause 18, wherein the noise parameter is capacitance.
20. The method of clause 18, wherein the noise parameter is junction capacitance.
21. The method of clause 18, wherein the second segment surrounds at least 50% of the first segment.
22. The method of clause 21, wherein the second segment completely surrounds the first segment.
23. The method of clause 18, wherein the first segment has a substantially rectangular-based shape.
24. The method of clause 23, wherein the substantially rectangular-based shape is a substantially square-based shape.
25. The method of clause 18, wherein the first segment has a dimension in a first direction of at least 1 mm.
26. The method of clause 18, wherein:
   a shape of the first detector region corresponds to a shape of a FOV on the sample surface in the first scan.
27. The method of clause 18, wherein:
   a shape of the second detector region corresponds to a shape of a FOV on the sample surface in the second scan.
28. The method of clause 18, further comprising:
   detecting charged particles at a third segment bordering at least a first side of the second detector region;
   detecting charged particles at a fourth segment bordering at least a second side of the second detector region, the second side being opposite the first side; and
   determining an alignment parameter based on the detected charged particles at the third segment and the fourth segment.
29. The method of clause 18, wherein the charged particle detector comprises an aperture located outside a border of the first segment.
30. The method of clause 29, wherein the aperture is located in the second segment.
31. The method of clause 18, wherein the first exposure setting or the second exposure setting comprises one of FOV size, landing energy, beam aperture setting, beam current, a lens setting, a deflector setting, and an image compensation unit setting.
32. The method of clause 18, wherein:
   the first exposure setting comprises a first FOV size;
   the second exposure setting comprises a second FOV size; and
   the second FOV size is larger than the first FOV size.
33. The method of clause 18, wherein:
   the first exposure setting comprises a first landing energy;
   the second exposure setting comprises a second landing energy; and
   the second landing energy is higher than the first landing energy.
34. The method of clause 18, wherein:
   the first exposure setting comprises a first beam aperture setting;
   the second exposure setting comprises a second beam aperture setting; and
   the second beam aperture setting is larger than the first beam aperture setting.
35. The method of clause 18, wherein:
   the first exposure setting comprises a first beam current;
   the second exposure setting comprises a second beam current; and
   the second beam current is larger than the first beam current.
36. The method of clause 18, wherein:
   the first detector region captures more than 90% of emitted charged particles from the first scan.
37. The method of clause 18, wherein:
   the second detector region is captures more than 90% of emitted charged particles from the second scan.
38. A non-transitory computer-readable medium that stores a set of instructions that is executable by at least one processor of an apparatus to cause the apparatus to perform a method comprising:
   performing a first scan of a sample surface with a charged particle beam under a first exposure setting to cause emitted charged particles from the sample surface to land in a first detector region of a charged particle detector, the first detector region comprising a first noise value of a noise parameter;
   generating a first image based on the first scan;
   performing a second scan of the sample surface with a charged particle beam under a second exposure setting to cause emitted charged particles from the sample surface to land in a second detector region of the charged particle detector, the second detector region comprising a second noise value of a noise parameter, the second noise value being higher than the first noise value; and
   generating a second image based on the second scan, the first image having a higher accuracy than the second image, wherein
   the first detector region comprises a first segment of the charged particle detector,
   the second detector region comprises the first segment and a second segment of the charged particle detector, and
   the second detector region is larger than the first detector region.
39. A method of detecting a charged particle event in a charged particle detector, comprising:
   selecting an exposure setting of a charged particle beam exposure apparatus;
   selecting a first detector region or a second detector region of the charged particle detector based on the exposure setting;
   performing a charged particle beam exposure under the selected exposure setting; and
   generating an image based on charged particle detection at the selected first detector region or second detector region, wherein
   the first detector region comprises a first segment of the charged particle detector and comprises a first noise value of a noise parameter,
   the second detector region comprises the first segment and a second segment of the charged particle detector and comprises a second noise value of the noise parameter, the second noise value being higher than the first noise value, and
   the second detector region is larger than the first detector region.
40. A non-transitory computer-readable medium that stores a set of instructions that is executable by at least one processor of an apparatus to cause the apparatus to perform a method comprising:
   selecting an exposure setting of a charged particle beam exposure apparatus;
   selecting a first detector region or a second detector region of a charged particle detector based on the exposure setting;
   performing a charged particle beam exposure under the selected exposure setting; and
   generating an image based on charged particle detection at the selected first detector region or second detector region, wherein
   the first detector region comprises a first segment of the charged particle detector and comprises a first noise value of a noise parameter,
   the second detector region comprises the first segment and a second segment of the charged particle detector and comprises a second noise value of the noise parameter, the second noise value being higher than the first noise value, and
   the second detector region is larger than the first detector region.
41. A charged particle detector, comprising:
   a top conductive layer comprising a detection surface;
   a bottom conductive layer;
   a semiconductor region between the top conductive layer and the bottom conductive layer, the semiconductor region comprising a first doped region of a first conductivity type adjacent the top conductive layer, a second doped region of a second conductivity type adjacent the bottom conductive layer, the second conductivity type being different from the first conductivity type, and an intrinsic region between the first doped region and the second doped region; and
   an aperture configured to allow a primary charged particle beam to pass through, wherein
   the detection surface extends to an edge of the aperture.
42. The charged particle detector of clause 41, wherein the detection surface extends to an entire perimeter of the edge of the aperture.
43. The charged particle detector of clause 41, wherein a sidewall that abuts the aperture comprises a further detection surface.
44. The charged particle detector of clause 41, wherein:
   the first doped region extends along the detection surface and along a sidewall of the aperture.
45. The charged particle detector of clause 44, wherein:
   the first doped region extends to a non-sensitive surface comprising a non-conductive material.
46. The charged particle detector of clause 41, further comprising:
   a non-sensitive surface comprising a non-conductive material, the non-sensitive surface surrounding the aperture and contacting one of the bottom conductive layer or the second doped region.
47. The charged particle detector of clause 46, wherein the non-sensitive surface comprises silicon dioxide (SiO₂).
48. The charged particle detector of clause 46, wherein the non-sensitive surface comprises an outer diameter of between 4 and 8 mm.
49. The charged particle detector of clause 41, wherein the aperture comprises a diameter of between 200 and 400 μm.
50. The charged particle detector of clause 41, wherein the top conductive layer comprises aluminum (Al).
51. The charged particle detector of clause 41, wherein the bottom conductive layer comprises one of titanium (Ti) or gold (Au).
52. The charged particle detector of clause 41, wherein the top conductive layer extends along a sidewall of the aperture.
53. The charged particle detector of clause 41, wherein the first doped region comprises a p-type dopant.
54. The charged particle detector of clause 53, wherein the p-type dopant comprises boron.
55. The charged particle detector of clause 41, wherein the second doped region comprises an n-type dopant.
56. The charged particle detector of clause 55, wherein the n-type dopant comprises one of arsenic, phosphorus, or antimony.

A non-transitory computer-readable medium may be provided that stores instructions for a processor of a controller (e.g., controller 109 in FIG. 1 or 2B, or image processing system 199 of FIG. 2B) for detecting charged particles according to, e.g., the exemplary flowcharts of FIGS. 8-9, consistent with embodiments of the present disclosure. For example, the instructions stored in the non-transitory computer-readable medium may be executed by the circuitry of the controller for performing method 800 or method 900 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes can be made without departing from the scope thereof. For example, a charged particle inspection system may be but one example of a charged particle beam system consistent with embodiments of the present disclosure.

1. A segmented multi-channel detector, comprising:
a first detector region having a first segment; and
a second detector region having the first segment and a second segment, the second segment surrounding at least 50% of the first segment, wherein
the first detector region comprises a first noise value of a noise parameter; and
the second detector region comprises a second noise value of the noise parameter, the second noise value being higher than the first noise value.

2. The segmented multi-channel detector of claim 1, wherein the noise parameter is capacitance.

3. The segmented multi-channel detector of claim 1, wherein the noise parameter is junction capacitance.

4. The segmented multi-channel detector of claim 1, wherein the second segment completely surrounds the first segment.

5. The segmented multi-channel detector of claim 1, wherein the first segment has a rectangular-based shape.

6. The segmented multi-channel detector of claim 5, wherein the rectangular-based shape is a square-based shape.

7. The segmented multi-channel detector of claim 1, wherein the first segment has a dimension in a first direction of at least 1 mm.

8. The segmented multi-channel detector of claim 1, wherein:
a shape of the first detector region corresponds to a shape of a first FOV on a sample surface in a charged particle beam apparatus.

9. The segmented multi-channel detector of claim 8, wherein:
a shape of the second detector region corresponds to a shape of a second FOV on the sample surface in the charged particle beam apparatus, the second FOV being larger than the first FOV.

10. The segmented multi-channel detector of claim 1, further comprising:
a third segment bordering at least a first side of the second detector region; and
a fourth segment bordering at least a second side of the second detector region, the second side being opposite the first side.

11. The segmented multi-channel detector of claim 1, further comprising an aperture located outside the first segment.

12. The segmented multi-channel detector of claim 11, wherein the aperture is located in the second segment.

13. A charged particle beam apparatus, comprising:
a charged particle beam source configured to generate a beam of primary charged particles;
a charged particle optical system configured to scan the beam of primary charged particles over a field of view (FOV) of a sample surface; and
the segmented multi-channel detector of claim 1.

14. The charged particle beam apparatus of claim 13, wherein:
a shape of the first detector region corresponds to a shape of the FOV on the sample surface.

15. The charged particle beam apparatus of claim 13, wherein:
a shape of the second detector region corresponds to a shape of the FOV on the sample surface.

16. The charged particle beam apparatus of claim 13, wherein:
the first detector region is configured to capture more than 90% of emitted charged particles from the scan of the beam over the FOV of the sample surface.

17. The charged particle beam apparatus of claim 13, wherein:
the second detector region is configured to capture more than 90% of emitted charged particles from the scan of the beam over the FOV of the sample surface.

18. A non-transitory computer-readable medium that stores a set of instructions that is executable by at least one processor of an apparatus to cause the apparatus to perform operations comprising:
performing a first scan of a sample surface with a charged particle beam under a first exposure setting to cause emitted charged particles from the sample surface to land in a first detector region of a charged particle detector, the first detector region comprising a first noise value of a noise parameter;
generating a first image based on the first scan;
performing a second scan of the sample surface with a charged particle beam under a second exposure setting to cause emitted charged particles from the sample surface to land in a second detector region of the charged particle detector, the second detector region comprising a second noise value of a noise parameter, the second noise value being higher than the first noise value; and
generating a second image based on the second scan, the first image having a higher accuracy than the second image, wherein
the first detector region comprises a first segment of the charged particle detector, the second detector region comprises the first segment and a second segment of the charged particle detector, and
the second detector region is larger than the first detector region.

19. The computer-readable medium of claim 18, wherein:
a shape of the first detector region corresponds to a shape of a first FOV on the sample surface in the first scan.

20. The computer-readable medium of claim 19, wherein:
a shape of the second detector region corresponds to a shape of a second FOV on the sample surface in the second scan, the shape of the second FOV being different than the shape of the first FOV.
